(19) United States
(12) Patent Application Publication
(10) Pub. No.: US 2026/0293199 A1
(43) Pub. Date: Sep. 24, 2026

(54) SEMICONDUCTOR DEVICE AND SEMICONDUCTOR DEVICE MANUFACTURING METHOD

(71) Applicant: KABUSHIKI KAISHA TOSHIBA, Kawasaki-shi (JP)

(72) Inventor: Tatsuo SHIMIZU, Shinagawa Tokyo (JP)

(73) Assignee: KABUSHIKI KAISHA TOSHIBA, Kawasaki-shi (JP)

(21) Appl. No.: 19/536,011

(22) Filed: Feb. 10, 2026

(30) Foreign Application Priority Data
Mar. 18, 2025 (JP) 2025-043047

(51) Int. Cl. H10D 30/66

(52) U.S. Cl. CPC H10D 30/668

(57) ABSTRACT

A semiconductor device of embodiments includes: a first electrode; a second electrode; a first nitride semiconductor region of n-type provided between the first electrode and the second electrode; a second nitride semiconductor region of p-type provided between the first nitride semiconductor region and the first electrode, in contact with the first nitride semiconductor region, and containing magnesium (Mg); a line defect provided spanning the first nitride semiconductor region and the second nitride semiconductor region; and a linear region including at least a part of the line defect, provided along the line defect, and containing carbon (C).

### CROSS-REFERENCE TO RELATED APPLICATION

This application is based upon and claims the benefit of priority from Japanese Patent Application No. 2025-043047, filed on Mar. 18, 2025, the entire contents of which are incorporated herein by reference.

### FIELD

Embodiments described herein relate generally to a semiconductor device and a semiconductor device manufacturing method.

### BACKGROUND

Semiconductor elements such as transistors and diodes are used in circuits such as switching power supply circuits and inverter circuits. These semiconductor elements are required to have high breakdown voltage and low on-resistance. There is a trade-off relationship between breakdown voltage and on-resistance, which is determined by the element material.

Due to advances in technological development, semiconductor elements have achieved low on-resistance close to the limit of silicon, which is the main element material. In order to further increase the breakdown voltage and further reduce the on-resistance, it is necessary to change the element material. By using a nitride semiconductor, such as gallium nitride or aluminum gallium nitride, as an element material of the semiconductor element, the trade-off relationship determined by the element material can be improved. Therefore, it is possible to dramatically increase the breakdown voltage and reduce the on-resistance of the semiconductor element.

When forming a semiconductor element using a nitride semiconductor, a pn junction formed by a p-type nitride semiconductor region and an n-type nitride semiconductor region may be provided in the nitride semiconductor. If the leakage current at the pn junction is large, the characteristics of the semiconductor element are degraded. For example, the power consumption of the semiconductor element increases. Therefore, it is desirable to reduce the leakage current at the pn junction.

### BRIEF DESCRIPTION OF THE DRAWINGS

FIG. 1 is a schematic cross-sectional view of a semiconductor device according to a first embodiment;

FIG. 2 is a diagram showing an example of a manufacturing flow of a semiconductor device manufacturing method according to a first embodiment;

FIG. 3 is a cross-sectional view showing an example of the semiconductor device manufacturing method according to the first embodiment;

FIG. 4 is a cross-sectional view showing an example of the semiconductor device manufacturing method according to the first embodiment;

FIG. 5 is a cross-sectional view showing an example of the semiconductor device manufacturing method according to the first embodiment;

FIG. 6 is a cross-sectional view showing an example of the semiconductor device manufacturing method according to the first embodiment;

FIG. 7 is a cross-sectional view showing an example of the semiconductor device manufacturing method according to the first embodiment;

FIG. 8 is a cross-sectional view showing an example of the semiconductor device manufacturing method according to the first embodiment;

FIG. 9 is a cross-sectional view showing an example of the semiconductor device manufacturing method according to the first embodiment;

FIG. 10 is a cross-sectional view showing an example of the semiconductor device manufacturing method according to the first embodiment;

FIG. 11 is a cross-sectional view showing an example of the semiconductor device manufacturing method according to the first embodiment;

FIG. 12 is a cross-sectional view showing an example of the semiconductor device manufacturing method according to the first embodiment;

FIG. 13 is a schematic cross-sectional view of a semiconductor device according to a comparative example;

FIG. 14 is a diagram showing an example of a manufacturing flow of a semiconductor device manufacturing method according to a comparative example;

FIG. 15 is a cross-sectional view showing an example of the semiconductor device manufacturing method according to the comparative example;

FIG. 16 is a cross-sectional view showing an example of the semiconductor device manufacturing method according to the comparative example;

FIG. 17 is a cross-sectional view showing an example of the semiconductor device manufacturing method according to the comparative example;

FIG. 18 is a cross-sectional view showing an example of the semiconductor device manufacturing method according to the comparative example;

FIG. 19 is a cross-sectional view showing an example of the semiconductor device manufacturing method according to the comparative example;

FIG. 20 is a cross-sectional view showing an example of the semiconductor device manufacturing method according to the comparative example;

FIG. 21 is a schematic cross-sectional view of a semiconductor device according to a first modification example of the first embodiment;

FIG. 22 is a schematic cross-sectional view of a semiconductor device according to a second modification example of the first embodiment;

FIG. 23 is a schematic cross-sectional view of a semiconductor device according to a third modification example of the first embodiment;

FIG. 24 is a schematic cross-sectional view of a semiconductor device according to a fourth modification example of the first embodiment; and

FIG. 25 is a schematic cross-sectional view of a semiconductor device according to a second embodiment.

### DETAILED DESCRIPTION

A semiconductor device of embodiments includes: a first electrode; a second electrode; a first nitride semiconductor region of n-type provided between the first electrode and the second electrode; a second nitride semiconductor region of p-type provided between the first nitride semiconductor region and the first electrode, in contact with the first nitride semiconductor region, and containing magnesium (Mg); a line defect provided spanning the first nitride semiconductor region and the second nitride semiconductor region; and a linear region including at least a part of the line defect, provided along the line defect, and containing carbon (C).

Hereinafter, embodiments will be described with reference to the accompanying diagrams. In the following description, the same or similar members will be denoted by the same reference numerals, and the description of the members once described may be omitted.

In this specification, the “nitride semiconductor layer” and the “nitride semiconductor region” contain “GaN-based semiconductor”. The “GaN-based semiconductor” is a general term for gallium nitride (GaN), aluminum nitride (AlN), indium nitride (InN), and semiconductors having an intermediate composition thereof.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

In addition, in the following description, when there are notations of n⁺, n, n⁻, p⁺, p, and p⁻, these indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, and p⁺-type and p⁻-type may be simply described as p-type.

For the qualitative analysis and quantitative analysis of the chemical composition of members forming the semiconductor device in this specification, it is possible to use, for example, secondary ion mass spectroscopy (SIMS), energy dispersive X-ray spectroscopy (EDX), and electron energy loss spectroscopy (EELS). In addition, when measuring the thickness of each member forming the semiconductor device, a distance between members, and the like, it is possible to use, for example, a transmission electron microscope (TEM) or a scanning electron microscope (SEM). In addition, the transmission electron microscope (TEM) can be used to identify crystal defects contained in a semiconductor device.

### First Embodiment

A semiconductor device according to a first embodiment includes: a first electrode; a second electrode; a first nitride semiconductor region of n-type provided between the first electrode and the second electrode; a second nitride semiconductor region of p-type provided between the first nitride semiconductor region and the first electrode, in contact with the first nitride semiconductor region, and containing magnesium (Mg); a line defect provided spanning the first nitride semiconductor region and the second nitride semiconductor region; and a linear region including at least a part of the line defect, provided along the line defect, and containing carbon (C).

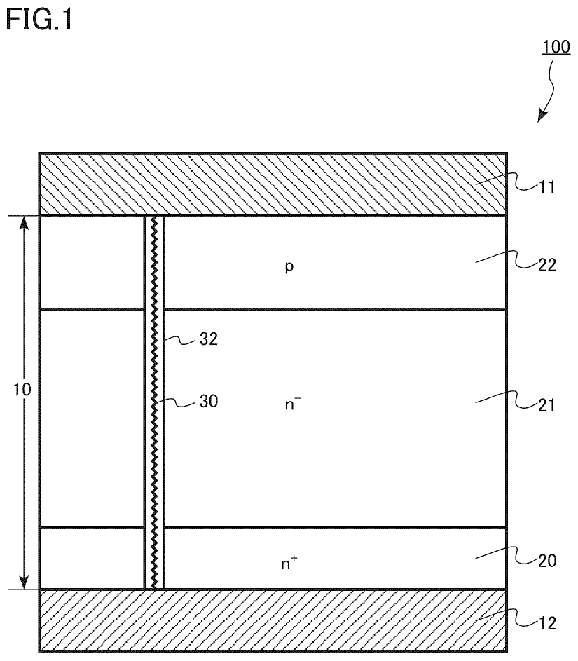

FIG. 1 is a schematic cross-sectional view of the semiconductor device according to the first embodiment. The semiconductor device according to the first embodiment is a pn junction diode 100.

The pn junction diode 100 includes a nitride semiconductor layer 10, an anode electrode 11 (first electrode), and a cathode electrode 12 (second electrode). The nitride semiconductor layer 10 includes an n⁺-type lower region 20 (third nitride semiconductor region), an n⁻-type intermediate region 21 (first nitride semiconductor region), a p-type upper region 22 (second nitride semiconductor region), and a line defect 30, and a linear carbon region 32 (linear region).

The anode electrode 11 and the cathode electrode 12 are formed of, for example, a metal. The anode electrode 11 is in contact with the upper region 22. The cathode electrode 12 is in contact with the lower region 20.

The nitride semiconductor layer 10 is provided between the anode electrode 11 and the cathode electrode 12. The nitride semiconductor layer 10 is in contact with the anode electrode 11 and the cathode electrode 12. The nitride semiconductor layer 10 is, for example, a gallium nitride.

The n⁺-type lower region 20 is in contact with the cathode electrode 12.

The lower region 20 contains n-type impurities. The n-type impurity is, for example, silicon (Si). The n-type impurity concentration of the lower region 20 is higher than the n-type impurity concentration of the intermediate region 21. The n-type impurity concentration of the lower region 20 is, for example, equal to or more than 1×10¹⁸ cm⁻³ and equal to or less than 1×10²¹ cm⁻³.

The n⁻-type intermediate region 21 is provided between the lower region 20 and the anode electrode 11. The intermediate region 21 is in contact with the lower region 20.

The intermediate region 21 contains n-type impurities. The n-type impurity is, for example, silicon (Si). The n-type impurity concentration of the intermediate region 21 is, for example, equal to or more than 1×10¹⁵ cm⁻³ and equal to or less than 1×10¹⁷ cm⁻³.

The intermediate region 21 contains or does not contain carbon (C).

The p-type upper region 22 is provided between the intermediate region 21 and the anode electrode 11. The upper region 22 is in contact with the intermediate region 21. The junction between the upper region 22 and the intermediate region 21 is a pn junction. The upper region 22 is in contact with the anode electrode 11.

The upper region 22 contains magnesium (Mg), which is a p-type impurity. The magnesium concentration of the upper region 22 is, for example, equal to or more than 1×10¹⁸ cm⁻³ and equal to or less than 1×10²¹ cm⁻³.

The upper region 22 contains or does not contain carbon (C).

The line defect 30 is provided spanning the intermediate region 21 and the upper region 22. The line defect 30 is provided, for example, spanning the lower region 20 and the intermediate region 21. The line defect 30 is provided, for example, continuously between the cathode electrode 12 and the anode electrode 11. The line defect 30 is in contact with, for example, the cathode electrode 12 and the anode electrode 11.

The line defect 30 is, for example, a threading dislocation. The line defect 30 is, for example, a threading screw dislocation (TSD).

The linear carbon region 32 includes at least a part of the line defect 30. The linear carbon region 32 is provided along the line defect 30.

The linear carbon region 32 is in contact with, for example, the intermediate region 21. The linear carbon region 32 is in contact with, for example, the upper region 22.

The linear carbon region 32 contains carbon (C). The carbon concentration of the linear carbon region 32 is, for example, higher than the carbon concentration of the intermediate region 21. In addition, the carbon concentration of the linear carbon region 32 is, for example, higher than the carbon concentration of the upper region 22. In the linear carbon region 32, carbon is piled up.

The width of the linear carbon region 32 in a second direction perpendicular to a first direction from the anode electrode 11 toward the cathode electrode 12 is, for example, smaller than the depth of the upper region 22 in the first direction. The width of the linear carbon region 32 in the second direction is, for example, equal to or less than 100 nm. The width of the linear carbon region 32 in the second direction is preferably equal to or less than 30 nm, more preferably equal to or less than 10 nm, and even more preferably equal to or less than 5 nm. In addition, nitrogen vacancies in the dislocation are present side by side within a width equal to or more than 0.1 nm. Therefore, the width of the linear carbon region 32 in the second direction is equal to or more than 0.1 nm.

The linear carbon region 32 extends along the line defect 30. The length of the linear carbon region 32 in its extension direction is larger than the width of the linear carbon region 32 in a direction perpendicular to the extension direction. The aspect ratio of the linear carbon region 32 is, for example, equal to or more than 3 and equal to or less than 500,000. The aspect ratio of the linear carbon region 32 is preferably equal to or more than 30 and equal to or less than 50,000, more preferably equal to or more than 50 and equal to or less than 10,000, and even more preferably equal to or more than 100 and equal to or less than 10,000. The aspect ratio of the linear carbon region 32 is a value obtained by dividing the length of the linear carbon region 32 in its extension direction by the width of the linear carbon region 32 in a direction perpendicular to the extension direction.

The length of the linear carbon region 32 in its extension direction and the width of the linear carbon region 32 in a direction perpendicular to the extension direction can be measured by using, for example, a three dimensional atom probe method.

Next, an example of a semiconductor device manufacturing method according to the first embodiment will be described.

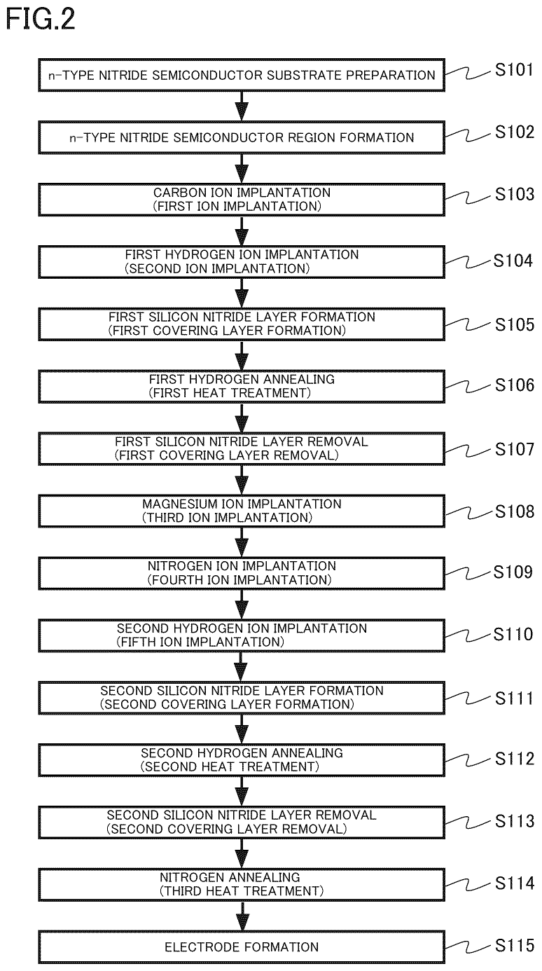

FIG. 2 is a diagram showing an example of a manufacturing flow of the semiconductor device manufacturing method according to the first embodiment.

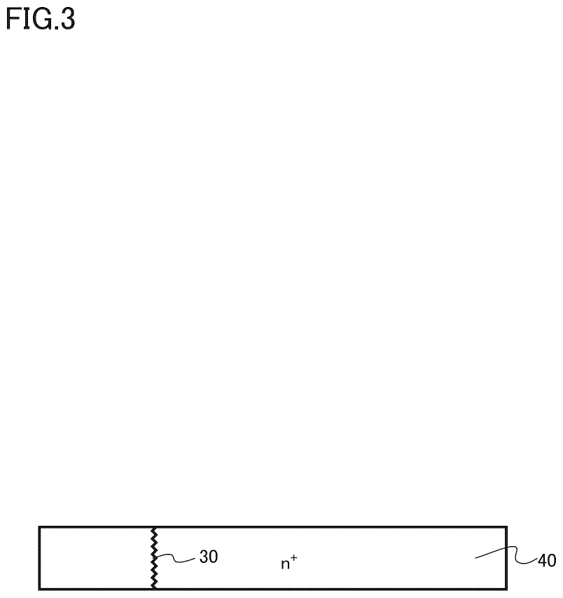

FIGS. 3 to 12 are cross-sectional views showing an example of the semiconductor device manufacturing method according to the first embodiment.

A semiconductor device manufacturing method according to the first embodiment includes: performing a first ion implantation to implant carbon (C) into an n-type nitride semiconductor layer; performing a second ion implantation to implant hydrogen (H) into the nitride semiconductor layer; forming a first covering layer on a surface of the nitride semiconductor layer after the first ion implantation and the second ion implantation; performing a first heat treatment after forming the first covering layer; removing the first covering layer; performing a third ion implantation to implant magnesium (Mg) into the nitride semiconductor layer after removing the first covering layer; performing a fourth ion implantation to implant nitrogen (N) into the nitride semiconductor layer; performing a fifth ion implantation to implant hydrogen (H) into the nitride semiconductor layer; forming a second covering layer on a surface of the nitride semiconductor layer after the third ion implantation, the fourth ion implantation, and the fifth ion implantation; performing a second heat treatment after forming the second covering layer; removing the second covering layer after the second heat treatment; and performing a third heat treatment after removing the second covering layer.

The semiconductor device manufacturing method according to the first embodiment includes an n-type nitride semiconductor substrate preparation step S101, an n-type nitride semiconductor region formation step S102, a carbon ion implantation step S103 (first ion implantation), a first hydrogen ion implantation step S104 (second ion implantation), a first silicon nitride layer formation step S105 (first covering layer formation), a first hydrogen annealing step S106 (first heat treatment), a first silicon nitride layer removal step S107 (first covering layer removal), a magnesium ion implantation step S108 (third ion implantation), a nitrogen ion implantation step S109 (fourth ion implantation), a second hydrogen ion implantation step S110 (fifth ion implantation), a second silicon nitride layer formation step S111 (second covering layer formation), a second hydrogen annealing step S112 (second heat treatment), a second silicon nitride layer removal step S113 (second covering layer removal), a nitrogen annealing step S114 (third heat treatment), and an electrode formation step S115.

First, an n-type nitride semiconductor substrate 40 is prepared (S101: FIG. 3). The n-type nitride semiconductor substrate 40 is, for example, an n⁺-type gallium nitride substrate. The n-type nitride semiconductor substrate 40 finally becomes the n⁺-type lower region 20.

The n-type nitride semiconductor substrate 40 includes the line defect 30. The line defect 30 is, for example, a threading screw dislocation. The line defect 30 includes nitrogen vacancies.

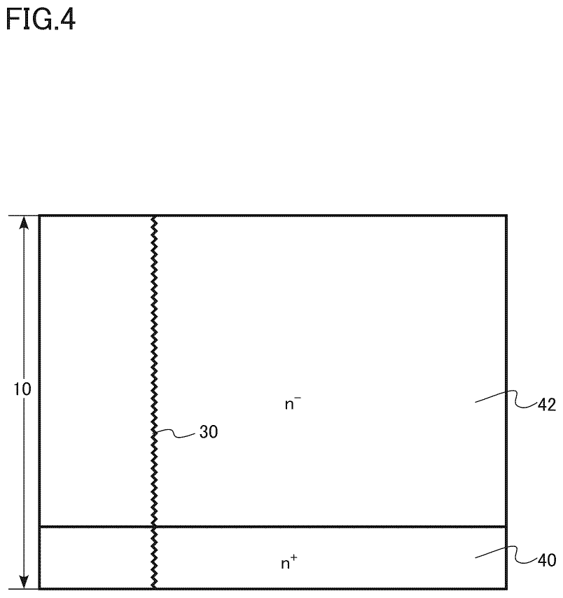

Then, an n-type nitride semiconductor region 42 is formed on the n-type nitride semiconductor substrate 40 (S102: FIG. 4). The n-type nitride semiconductor region 42 is, for example, an n⁻type gallium nitride region.

The n-type nitride semiconductor region 42 is formed by using, for example, an epitaxial growth method. The line defect 30 in the n-type nitride semiconductor substrate 40 extends to the n-type nitride semiconductor region 42.

The n-type nitride semiconductor substrate 40 and the n-type nitride semiconductor region 42 form the n-type nitride semiconductor layer 10.

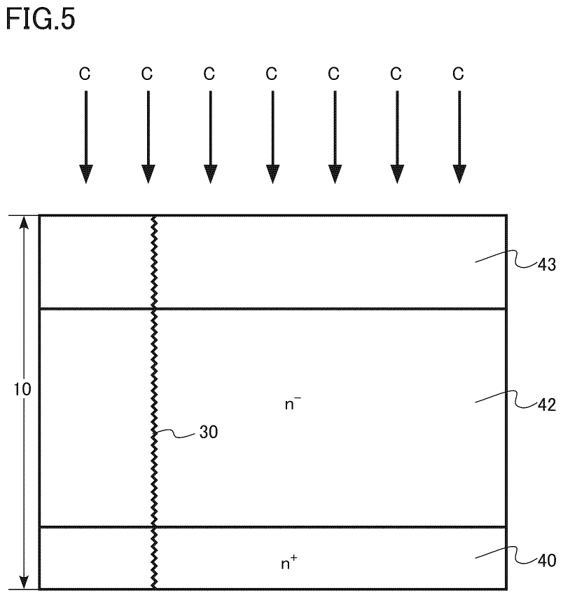

Then, carbon ion implantation is performed (S103: FIG. 5). Carbon (C) is ion-implanted onto the surface of the nitride semiconductor layer 10 using a known ion implantation method. The carbon ion implantation corresponds to the first ion implantation.

By the carbon ion implantation, a carbon region 43 is formed in the nitride semiconductor layer 10. The carbon dose is, for example, equal to or more than 1×10¹² cm⁻² and equal to or less than 2×10¹⁴ cm⁻².

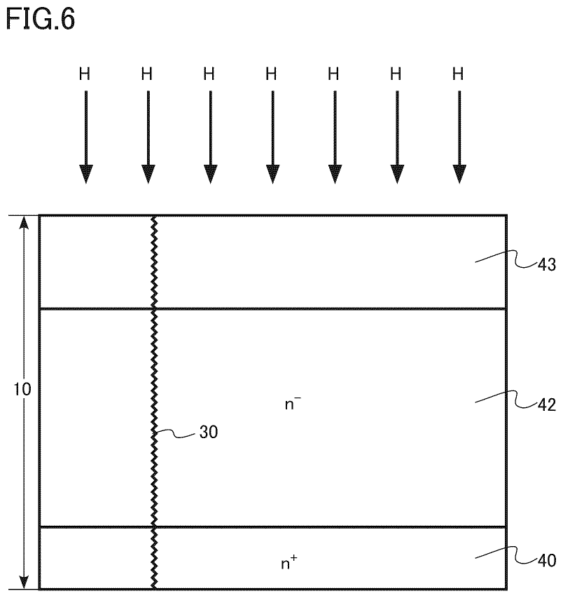

Then, the first hydrogen ion implantation is performed (S104: FIG. 6). Hydrogen (H) is ion-implanted onto the surface of the nitride semiconductor layer 10 using a known ion implantation method. The first hydrogen ion implantation corresponds to the second ion implantation.

By the first hydrogen ion implantation, hydrogen is introduced into the carbon region 43. The hydrogen dose in the first hydrogen ion implantation is, for example, larger than the carbon dose in the carbon ion implantation. The hydrogen dose is, for example, equal to or more than 1×10¹⁵ cm⁻² and equal to or less than 1×10¹⁶ cm⁻².

In addition, the first hydrogen ion implantation can also be performed before the carbon ion implantation.

Then, a first silicon nitride layer 45 is formed on the surface of the nitride semiconductor layer 10 using a known film growth method (S105). The first silicon nitride layer 45 is an example of a first covering layer.

The first covering layer is not limited to silicon nitride. The first covering layer is, for example, an insulator. The first covering layer is, for example, a silicon oxide, a silicon nitride, a silicon oxynitride, or an aluminum nitride.

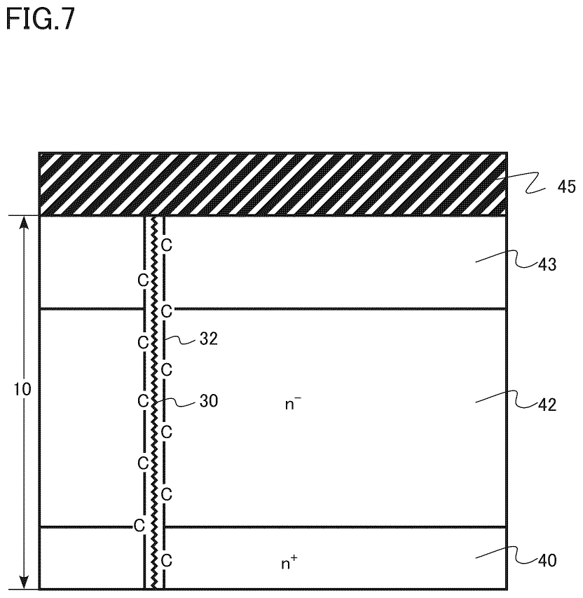

Then, first hydrogen annealing is performed (S106: FIG. 7). The first hydrogen annealing is performed, for example, in a hydrogen gas atmosphere under the conditions of temperature equal to or more than 400° C. and equal to or less than 900° C. The first hydrogen annealing is an example of the first heat treatment.

The atmosphere for the first heat treatment is not limited to the hydrogen gas atmosphere. The first heat treatment is performed in a non-oxidizing atmosphere containing argon, nitrogen, or helium, for example.

By the first hydrogen annealing, carbon in the carbon region 43 diffuses along the line defect 30 to form the linear carbon region 32. Carbon is piled up in the linear carbon region 32.

Carbon diffuses as hydrogen-bonded carbon. The hydrogen-bonded carbon fills the nitrogen vacancies of the line defect 30. In other words, the hydrogen-bonded carbon enters the nitrogen sites of the line defect 30. By forming hydrogen-bonded carbon, carbon more easily enters the nitrogen sites of the line defect 30.

The first silicon nitride layer 45 suppresses the release of hydrogen from the nitride semiconductor layer 10 during the first hydrogen annealing.

Then, the first silicon nitride layer 45 on the surface of the nitride semiconductor layer 10 is removed by using a known wet etching method (S107). The surface of the nitride semiconductor layer 10 is exposed.

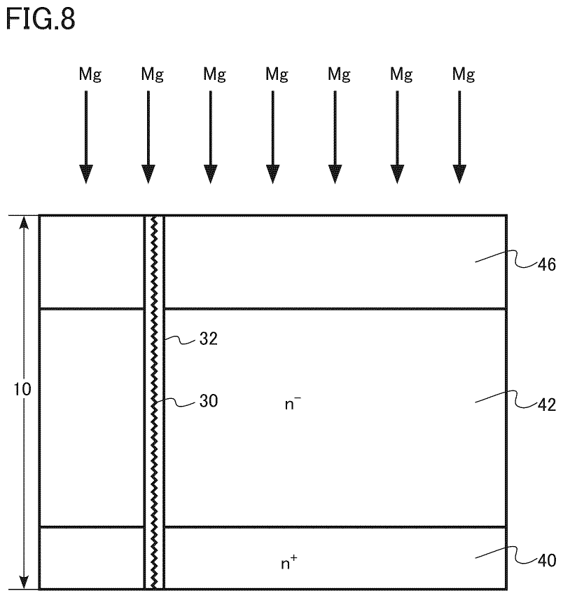

Then, magnesium ion implantation is performed (S108: FIG. 8). Magnesium (Mg) is ion-implanted onto the surface of the nitride semiconductor layer 10 using a known ion implantation method. The magnesium ion implantation corresponds to the third ion implantation.

By the magnesium ion implantation, a magnesium region 46 is formed in the nitride semiconductor layer 10. The magnesium region 46 finally becomes the upper region 22.

The magnesium dose is, for example, equal to or more than 1×10¹¹ cm⁻² and equal to or less than 1×10¹⁵ cm⁻².

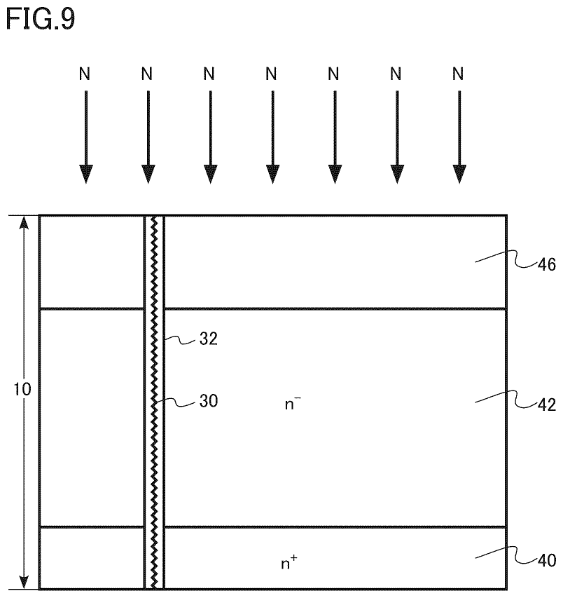

Then, nitrogen ion implantation is performed (S109: FIG. 9). Nitrogen (N) is ion-implanted onto the surface of the nitride semiconductor layer 10 using a known ion implantation method. The nitrogen ion implantation corresponds to the fourth ion implantation. Nitrogen is introduced into the magnesium region 46.

The nitrogen dose in the nitrogen ion implantation is larger than, for example, the magnesium dose in the magnesium ion implantation. The nitrogen dose is, for example, equal to or more than 1×10¹¹ cm⁻² and equal to or less than 1×10¹⁵ cm^{-2 .}

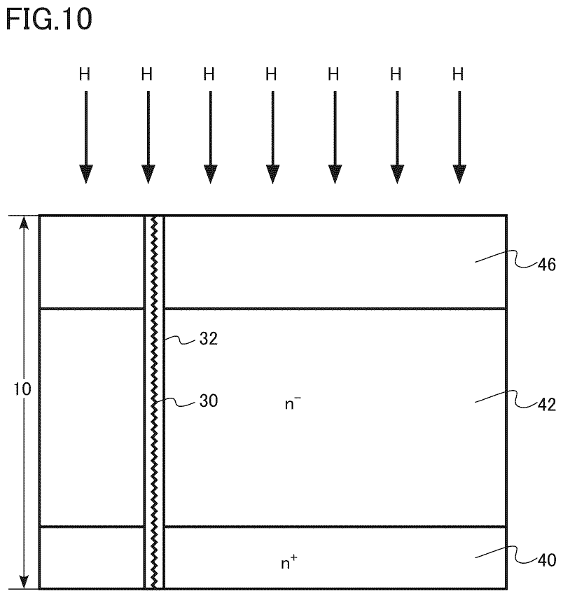

Then, second hydrogen ion implantation is performed (S110: FIG. 10). Hydrogen (H) is ion-implanted onto the surface of the nitride semiconductor layer 10 using a known ion implantation method. The second hydrogen ion implantation corresponds to the fifth ion implantation. Hydrogen is introduced into the magnesium region 46.

The hydrogen dose in the second hydrogen ion implantation is, for example, larger than the magnesium dose in the magnesium ion implantation. The hydrogen dose in the second hydrogen ion implantation is, for example, larger than the nitrogen dose in the nitrogen ion implantation. The hydrogen dose is, for example, equal to or more than 1×10¹⁵ cm⁻² and equal to or less than 1×10¹⁶ cm⁻².

In addition, the order of the magnesium ion implantation, the nitrogen ion implantation, and the second hydrogen ion implantation may be changed.

Then, a second silicon nitride layer 47 is formed on the surface of the nitride semiconductor layer 10 using a known film growth method (S111). The second silicon nitride layer 47 is an example of a second covering layer.

The second covering layer is not limited to silicon nitride. The second covering layer is, for example, an insulator. The second covering layer is, for example, a silicon oxide, a silicon nitride, a silicon oxynitride, or an aluminum nitride.

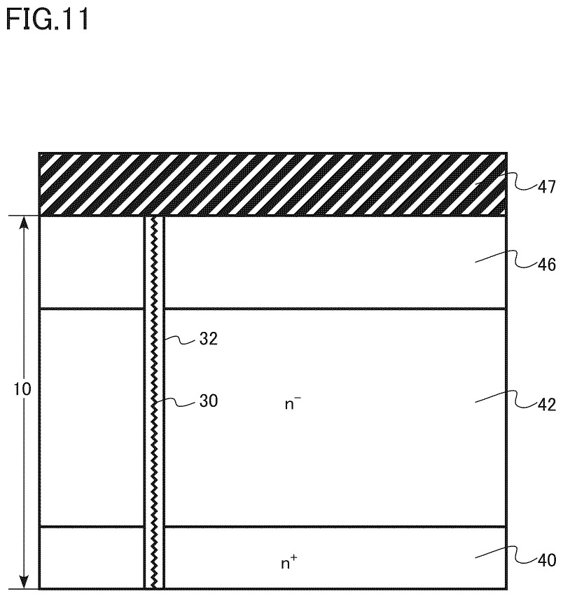

Then, second hydrogen annealing is performed (S111: FIG. 11). The second hydrogen annealing is performed, for example, in a hydrogen gas atmosphere under the conditions of temperature equal to or more than 900° C. and equal to or less than 1200° C. The second hydrogen annealing is an example of the second heat treatment.

The atmosphere for the second heat treatment is not limited to the hydrogen gas atmosphere. The second heat treatment is performed in a non-oxidizing atmosphere containing argon, nitrogen, or helium, for example.

By the second hydrogen annealing, magnesium in the magnesium region 46 enters the gallium sites of the gallium nitride. Magnesium enters the gallium sites as hydrogen-bonded magnesium. By forming hydrogen-bonded magnesium, magnesium more easily enters the gallium sites.

In addition, since the nitrogen introduced into the magnesium region 46 fills the nitrogen vacancies in the magnesium region 46, hydrogen-bonded magnesium more easily enters the gallium sites rather than the nitrogen sites.

The second silicon nitride layer 47 suppresses the release of hydrogen from the nitride semiconductor layer 10 during the second hydrogen annealing.

Then, the second silicon nitride layer 47 on the surface of the nitride semiconductor layer 10 is removed by using a known wet etching method (S113). The surface of the nitride semiconductor layer 10 is exposed.

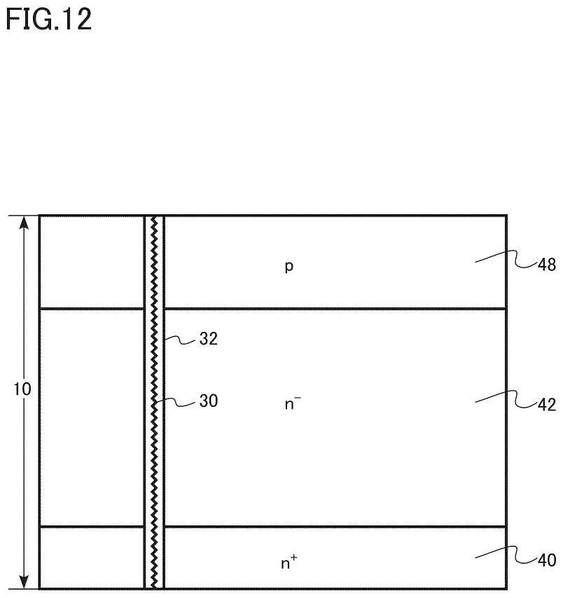

Then, nitrogen annealing is performed (S114: FIG. 12). The nitrogen annealing is performed, for example, in a nitrogen gas atmosphere under the conditions of temperature equal to or more than 900° C. and equal to or less than 1200° C. The nitrogen annealing is an example of the third heat treatment.

The third heat treatment is performed in a non-oxidizing atmosphere containing argon, nitrogen, or helium, for example. The third heat treatment is performed, for example, in a hydrogen-free atmosphere.

Since the second silicon nitride layer 47 has been removed, the release of hydrogen from the nitride semiconductor layer 10 is promoted during nitrogen annealing.

By the third heat treatment, the hydrogen of the hydrogen-bonded carbon that has entered the nitrogen sites of the line defect 30 is separated from the carbon, and only the carbon is left in the nitrogen sites to be activated. The activated carbon functions as a p-type impurity. The activated carbon functions as an acceptor.

In addition, by the third heat treatment, the hydrogen of the hydrogen-bonded magnesium that has entered the gallium sites of the magnesium region 46 is separated from the magnesium, and only the magnesium is left in the gallium sites to be activated. The activated magnesium functions as a p-type impurity. The activated magnesium functions as an acceptor.

By the activation of magnesium, a p-type impurity region 48 is formed.

Then, electrodes are formed (S115). The anode electrode 11 and the cathode electrode 12 are formed using a known manufacturing method.

By the manufacturing method described above, the pn junction diode 100 shown in FIG. 1 is manufactured.

Hereinafter, the function and effect of the semiconductor device manufacturing method according to the first embodiment will be described.

When forming a semiconductor element using a nitride semiconductor, a pn junction formed by a p-type nitride semiconductor region and an n-type nitride semiconductor region may be provided in the nitride semiconductor. If the leakage current at the pn junction is large, the characteristics of the semiconductor element are degraded. For example, the power consumption of the semiconductor element increases. Therefore, it is desirable to reduce the leakage current at the pn junction.

According to the semiconductor device and the semiconductor device manufacturing method of the first embodiment, it is possible to reduce the leakage current at the pn junction. Hereinafter, detailed explanation will be given.

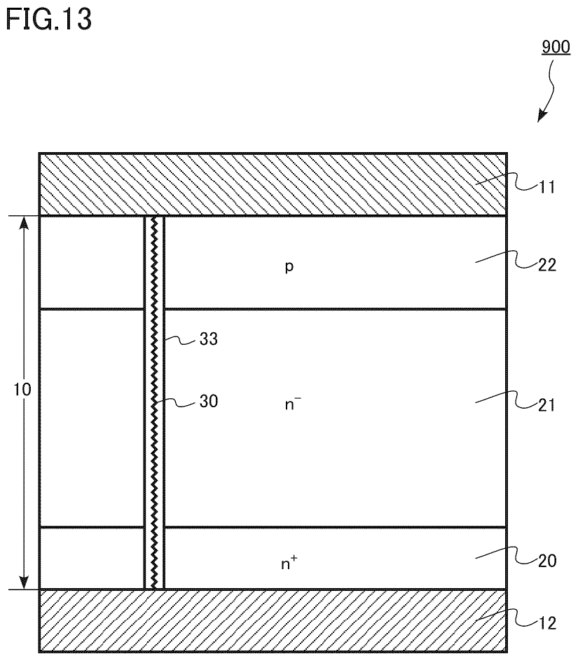

FIG. 13 is a schematic cross-sectional view of a semiconductor device according to a comparative example. The semiconductor device according to the comparative example is a pn junction diode 900.

The pn junction diode 900 includes a nitride semiconductor layer 10, an anode electrode 11, and a cathode electrode 12. The nitride semiconductor layer 10 includes an n⁺-type lower region 20, an n⁻-type intermediate region 21, a p-type upper region 22, a line defect 30, and a linear magnesium region 33.

The pn junction diode 900 according to the comparative example is different from the pn junction diode 100 according to the first embodiment in that the pn junction diode 900 includes the linear magnesium region 33 instead of the linear carbon region 32.

The linear magnesium region 33 includes at least a part of the line defect 30. The linear magnesium region 33 is provided along the line defect 30.

The linear magnesium region 33 is in contact with, for example, the intermediate region 21. The linear magnesium region 33 is in contact with, for example, the upper region 22.

The linear magnesium region 33 contains magnesium (Mg). The magnesium concentration of the linear magnesium region 33 is, for example, higher than the magnesium concentration of the intermediate region 21. In addition, the magnesium concentration of the linear magnesium region 33 is, for example, higher than the magnesium concentration of the upper region 22. In the linear magnesium region 33, magnesium is piled up.

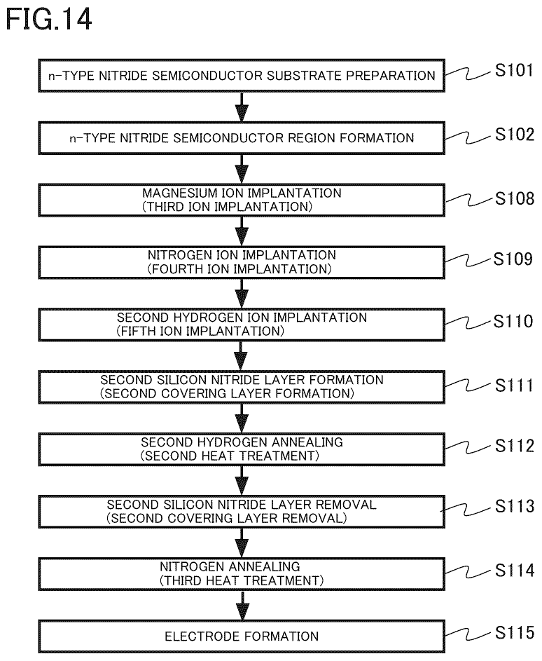

FIG. 14 is a diagram showing an example of a manufacturing flow of a semiconductor device manufacturing method according to a comparative example.

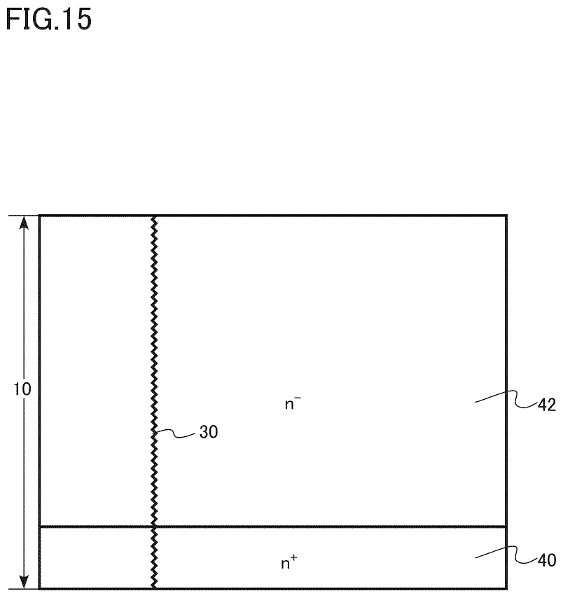

FIGS. 15 to 20 are cross-sectional views showing an example of the semiconductor device manufacturing method according to the comparative example.

The semiconductor device manufacturing method according to the comparative example is different from the semiconductor device manufacturing method according to the first embodiment in that the semiconductor device manufacturing method according to the comparative example does not include the first ion implantation for implanting carbon (C) and the second ion implantation for implanting hydrogen (H).

The semiconductor device manufacturing method according to the comparative example includes an n-type nitride semiconductor substrate preparation step S101, an n-type nitride semiconductor region formation step S102, a magnesium ion implantation step S108 (third ion implantation), a nitrogen ion implantation step S109 (fourth ion implantation), a second hydrogen ion implantation step S110 (fifth ion implantation), a second silicon nitride layer formation step S111 (second covering layer formation), a second hydrogen annealing step S112 (second heat treatment), a second silicon nitride layer removal step S113 (second covering layer removal), a nitrogen annealing step S114 (third heat treatment), and an electrode formation step S115.

The steps up to forming the n-type nitride semiconductor region 42 on the n-type nitride semiconductor substrate 40 (S102: FIG. 15) are the same as those in the semiconductor device manufacturing method according to the first embodiment.

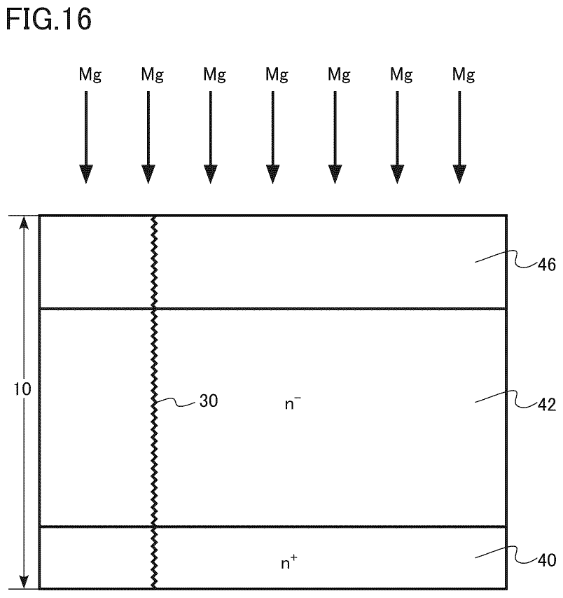

Then, magnesium ion implantation is performed (S108: FIG. 16). Magnesium (Mg) is ion-implanted onto the surface of the nitride semiconductor layer 10 using a known ion implantation method. The magnesium ion implantation corresponds to the third ion implantation.

By the magnesium ion implantation, a magnesium region 46 is formed in the nitride semiconductor layer 10. The magnesium region 46 finally becomes the upper region 22.

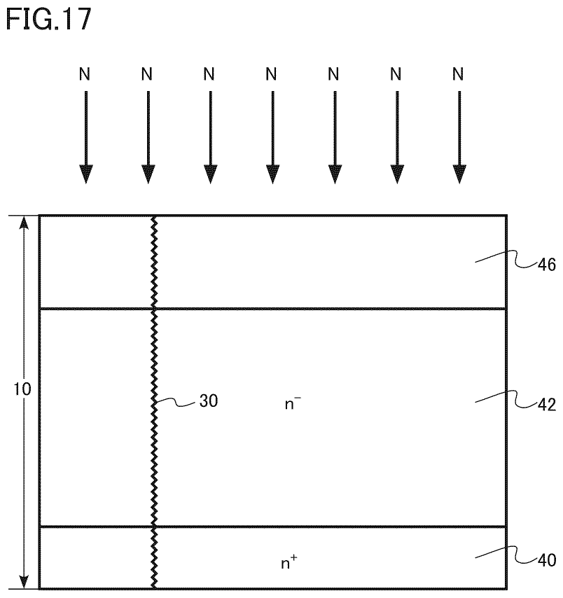

Then, nitrogen ion implantation is performed (S109: FIG. 17). Nitrogen (N) is ion-implanted onto the surface of the nitride semiconductor layer 10 using a known ion implantation method. The nitrogen ion implantation corresponds to the fourth ion implantation. Nitrogen is introduced into the magnesium region 46.

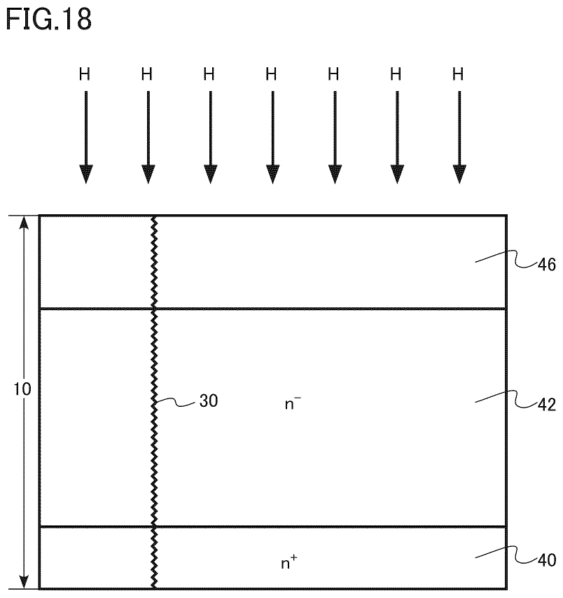

Then, second hydrogen ion implantation is performed (S110: FIG. 18). Hydrogen (H) is ion-implanted onto the surface of the nitride semiconductor layer 10 using a known ion implantation method. The second hydrogen ion implantation corresponds to the fifth ion implantation. Hydrogen is introduced into the magnesium region 46.

Then, a second silicon nitride layer 47 is formed on the surface of the nitride semiconductor layer 10 using a known film growth method (S111).

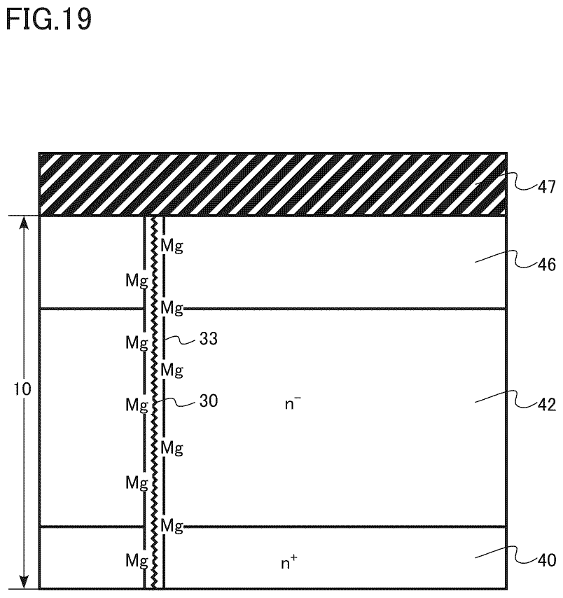

Then, second hydrogen annealing is performed (S112: FIG. 19). The second hydrogen annealing is performed, for example, in a hydrogen gas atmosphere under the conditions of temperature equal to or more than 900° C. and equal to or less than 1200° C.

By the second hydrogen annealing, magnesium in the magnesium region 46 enters the gallium sites of the gallium nitride. Magnesium enters the gallium sites as hydrogen-bonded magnesium. By forming hydrogen-bonded magnesium, magnesium more easily enters the gallium sites.

In addition, since the nitrogen introduced into the magnesium region 46 fills the nitrogen vacancies in the magnesium region 46, hydrogen-bonded magnesium more easily enters the gallium sites rather than the nitrogen sites.

The second silicon nitride layer 47 suppresses the release of hydrogen from the nitride semiconductor layer 10 during the second hydrogen annealing.

In addition, by the second hydrogen annealing, magnesium in the magnesium region 46 diffuses along the line defect 30 to form the linear magnesium region 33. Magnesium is piled up in the linear magnesium region 33.

Then, the second silicon nitride layer 47 on the surface of the nitride semiconductor layer 10 is removed by using a known wet etching method (S113). The surface of the nitride semiconductor layer 10 is exposed.

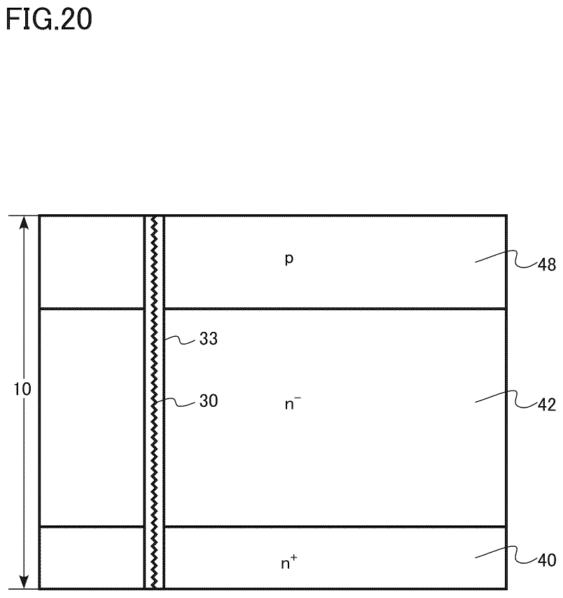

Then, nitrogen annealing is performed (S114: FIG. 20). The nitrogen annealing is performed, for example, in a nitrogen gas atmosphere under the conditions of temperature equal to or more than 900° C. and equal to or less than 1200° C. The nitrogen annealing is an example of the third heat treatment.

Since the second covering layer has been removed, the release of hydrogen from the nitride semiconductor layer 10 is promoted during nitrogen annealing.

By the third heat treatment, the hydrogen of the hydrogen-bonded magnesium that has entered the gallium sites of the magnesium region 46 is separated from the magnesium, and only the magnesium is left in the gallium sites to be activated. The activated magnesium functions as a p-type impurity. The activated magnesium functions as an acceptor.

By the activation of magnesium, a p-type impurity region 48 is formed.

Then, electrodes are formed (S115). The anode electrode 11 and the cathode electrode 12 are formed using a known manufacturing method.

By the manufacturing method described above, the pn junction diode 900 shown in FIG. 13 is manufactured.

The pn junction diode 900 according to the comparative example has a problem in that the leakage current at the pn junction between the upper region 22 and the intermediate region 21 is large.

As a result of first principle calculation performed by the inventors, it has become clear that when interstitial magnesium and nitrogen vacancies are present in gallium nitride, the magnesium is stabilized by entering the nitrogen vacancies. When interstitial magnesium and nitrogen vacancies are present in gallium nitride, there is a gain of approximately 1.9 eV due to the magnesium entering the nitrogen vacancies.

In the method of manufacturing the pn junction diode 900 according to the comparative example, magnesium is introduced by magnesium ion implantation to form the p-type upper region 22. The introduced magnesium is present as interstitial magnesium immediately after ion implantation. The interstitial magnesium is considered to diffuse along the nitrogen vacancies of the line defect 30 by the second hydrogen annealing and fill the nitrogen vacancies of the line defect 30.

In addition, as a result of first principle calculation performed by the inventors, it has become clear that when magnesium enters nitrogen vacancies in gallium nitride, electrons are supplied to the bottom of the conduction band of gallium nitride, causing the gallium nitride to become an n-type metal. That is, it has become clear that when magnesium enters nitrogen vacancies, gallium nitride becomes a metallic state having a work function corresponding to the energy of the bottom of the conduction band of gallium nitride.

In the pn junction diode 900 according to the comparative example, it is believed that the linear magnesium region 33 becomes an n-type metal, causing an increase in the leakage current at the PN junction between the upper region 22 and the intermediate region 21. As a leakage current path, for example, a path may be considered in which current flows from the n⁻ -type intermediate region 21 to the p-type upper region 22 through the linear magnesium region 33. In addition, for example, a path may be considered in which current flows directly from the cathode electrode 12 to the anode electrode 11 through the linear magnesium region 33.

The pn junction diode 100 according to the first embodiment includes the linear carbon region 32 instead of the linear magnesium region 33.

As a result of first principle calculation performed by the inventors, it has become clear that when interstitial carbon and nitrogen vacancies are present in gallium nitride, the carbon is stabilized by entering the nitrogen vacancies. When interstitial carbon and nitrogen vacancies are present in gallium nitride, there is a gain of approximately 6.4 eV due to the carbon entering the nitrogen vacancies.

In the method of manufacturing the pn junction diode 100 according to the first embodiment, carbon is introduced by carbon ion implantation before the formation of the p-type upper region 22. The introduced carbon is present as interstitial carbon immediately after ion implantation. The interstitial carbon diffuses along the nitrogen vacancies of the line defect 30 by the first hydrogen annealing and fills the nitrogen vacancies of the line defect 30.

When performing magnesium ion implantation to form the p-type upper region 22, the nitrogen vacancies of the line defect 30 have already been filled with carbon. That is, the linear carbon region 32 is formed.

Therefore, even if magnesium is introduced by magnesium ion implantation to form the p-type upper region 22, the linear magnesium region 33 is not formed.

When carbon enters the nitrogen vacancies in gallium nitride, the carbon functions as a p-type impurity. The activated carbon functions as an acceptor. Therefore, the linear carbon region 32 becomes a p-type semiconductor. Since the linear carbon region 32 is a p-type semiconductor, the linear carbon region 32 has a higher electrical resistance than the linear magnesium region 33, which is an n-type metal.

Therefore, the leakage current at the pn junction between the upper region 22 and the intermediate region 21 is reduced. As a result, it is possible to realize the pn junction diode 100 with reduced leakage current at the pn junction.

### First Modification Example

A semiconductor device according to a first modification example of the first embodiment is different from the semiconductor device according to the first embodiment in that a linear region includes only a part of a line defect.

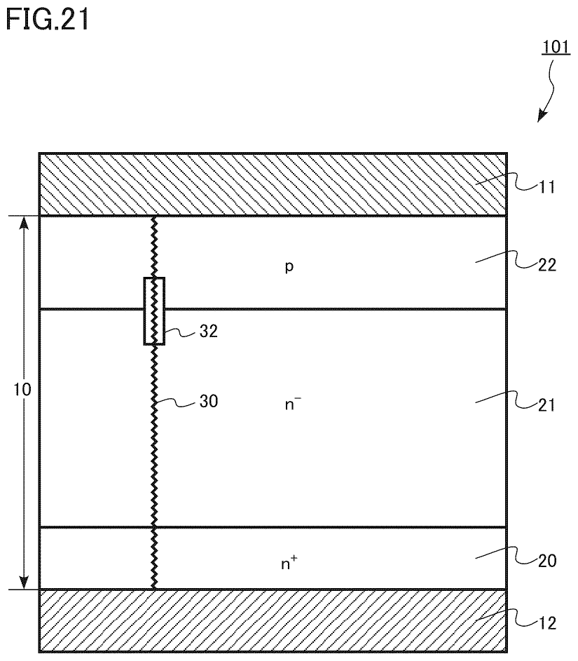

FIG. 21 is a schematic cross-sectional view of the semiconductor device according to the first modification example of the first embodiment. The semiconductor device according to the first modification example of the first embodiment is a pn junction diode 101.

A linear carbon region 32 of the pn junction diode 101 includes only a portion of the line defect 30 that spans the intermediate region 21 and the upper region 22. The linear carbon region 32 includes only a part of the line defect 30 in the upper region 22 and a part of the line defect 30 in the intermediate region 21.

For example, the above structure can be realized by limiting the distribution of carbon introduced into the nitride semiconductor layer 10 to the vicinity of the boundary between the intermediate region 21 and the upper region 22 during the carbon ion implantation shown in FIG. 5 of the first embodiment. By reducing the amount of carbon introduced into the nitride semiconductor layer 10, it becomes easier to recover from damage caused by ion implantation.

The linear carbon region 32 spans the intermediate region 21 and the upper region 22. The linear carbon region 32 is in contact with, for example, the intermediate region 21. The linear carbon region 32 is in contact with, for example, the upper region 22.

According to the first modification example, since the linear carbon region 32 is provided in a part of the line defect 30, the leakage current at the pn junction can be suppressed even if a linear magnesium region of low resistance n-type metal is formed in another part of the line defect 30. That is, the leakage current flowing from the n⁻-type intermediate region 21 to the p-type upper region 22 through the linear magnesium region can be suppressed.

According to the first modification example, as in the first embodiment, it is possible to realize the pn junction diode 101 with reduced leakage current at the pn junction.

### Second Modification Example

A semiconductor device according to a second modification example of the first embodiment is different from the semiconductor device according to the first embodiment in that a linear region includes only a part of a line defect.

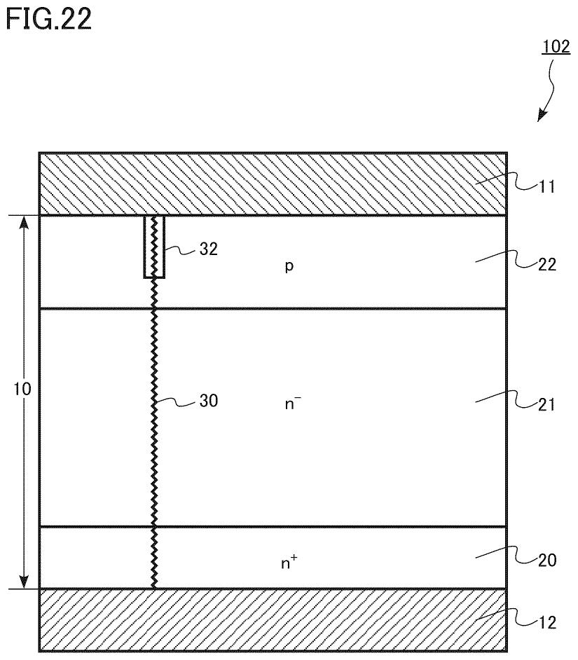

FIG. 22 is a schematic cross-sectional view of the semiconductor device according to the second modification example of the first embodiment. The semiconductor device according to the second modification example of the first embodiment is a pn junction diode 102.

A linear carbon region 32 of the pn junction diode 102 includes only a part of the line defect 30 in the upper region 22. The linear carbon region 32 is in contact with, for example, the upper region 22. The linear carbon region 32 is in contact with, for example, the anode electrode 11.

For example, the above structure can be realized by limiting the distribution of carbon introduced into the nitride semiconductor layer 10 to the side of the upper region 22 in contact with the anode electrode 11 during the carbon ion implantation shown in FIG. 5 of the first embodiment. By reducing the amount of carbon introduced into the nitride semiconductor layer 10, it becomes easier to recover from damage caused by ion implantation.

According to the second modification example, since the linear carbon region 32 is provided in a part of the line defect 30, the leakage current at the pn junction can be suppressed even if a linear magnesium region of low resistance n-type metal is formed in another part of the line defect 30. That is, the leakage current flowing directly from the cathode electrode 12 to the anode electrode 11 through the linear magnesium region 33 can be suppressed.

According to the second modification example, as in the first embodiment, it is possible to realize the pn junction diode 102 with reduced leakage current at the pn junction.

### Third Modification Example

A semiconductor device according to a third modification example of the first embodiment is different from the semiconductor device according to the first embodiment in that a linear region includes only a part of a line defect.

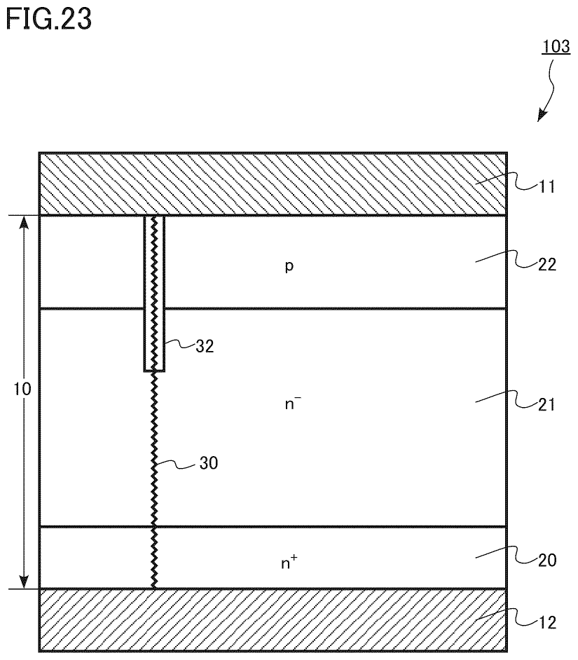

FIG. 23 is a schematic cross-sectional view of the semiconductor device according to the third modification example of the first embodiment. The semiconductor device according to the third modification example of the first embodiment is a pn junction diode 103.

A linear carbon region 32 of the pn junction diode 103 includes a line defect 30 in the upper region 22 and only a part of the line defect 30 in the intermediate region 21. The linear carbon region 32 is in contact with, for example, the upper region 22. The linear carbon region 32 is in contact with, for example, the anode electrode 11.

According to the third modification example, since the linear carbon region 32 is provided in a part of the line defect 30, the leakage current at the pn junction can be suppressed even if a linear magnesium region of low resistance n-type metal is formed in another part of the line defect 30. That is, the leakage current flowing from the n⁻-type intermediate region 21 to the p-type upper region 22 through the linear magnesium region can be suppressed. In addition, the leakage current flowing directly from the cathode electrode 12 to the anode electrode 11 through the linear magnesium region 33 can be suppressed.

According to the third modification example, as in the first embodiment, it is possible to realize the pn junction diode 103 with reduced leakage current at the pn junction.

### Fourth Modification Example

A semiconductor device according to a fourth modification example of the first embodiment is different from the semiconductor device according to the first embodiment in that the line defect is not in contact with the anode electrode 11.

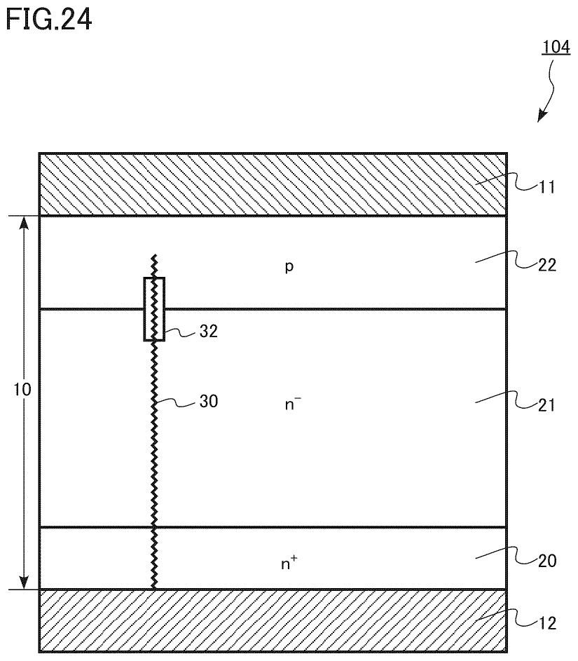

FIG. 24 is a schematic cross-sectional view of the semiconductor device according to the fourth modification example of the first embodiment. The semiconductor device according to the fourth modification example of the first embodiment is a pn junction diode 104.

A line defect 30 of the pn junction diode 104 terminates in the upper region 22.

According to the fourth modification example, as in the first embodiment, it is possible to realize the pn junction diode 104 with reduced leakage current at the pn junction.

As described above, according to the first embodiment and its modification examples, it is possible to realize a semiconductor device with reduced leakage current at the pn junction and a method of manufacturing the semiconductor device.

### Second Embodiment

A semiconductor device according to a second embodiment is different from the semiconductor device according to the first embodiment in that the semiconductor device according to the second embodiment is a transistor. Hereinafter, the description of a part of the content overlapping the first embodiment may be omitted.

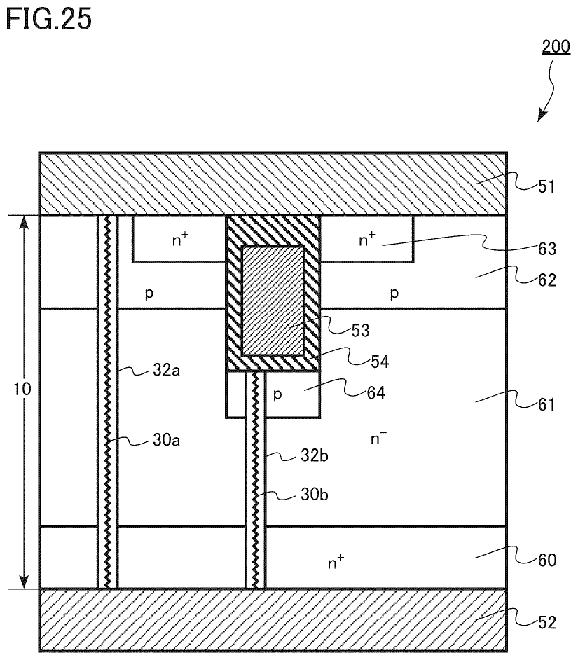

FIG. 25 is a schematic cross-sectional view of the semiconductor device according to the second embodiment. The semiconductor device according to the second embodiment is a vertical transistor 200. The vertical transistor 200 is a trench gate type metal oxide field effect transistor (MOSFET) in which a gate electrode is provided inside a trench.

The vertical transistor 200 includes a nitride semiconductor layer 10, a source electrode 51 (first electrode), a drain electrode 52 (second electrode), a gate electrode 53, and a gate insulating layer 54. The nitride semiconductor layer 10 includes an n⁺-type drain region 60 (third nitride semiconductor region), an n⁻-type drift region 61 (first nitride semiconductor region), a p-type base region 62 (second nitride semiconductor region), an n⁺-type source region 63, a p-type electric field relaxation region 64 (second nitride semiconductor region), a first line defect 30a (line defect), a second line defect 30b (line defect), a first linear carbon region 32a (linear region), and a second linear carbon region 32b (linear region).

The source electrode 51 and the drain electrode 52 are formed of, for example, a metal. The source electrode 51 is in contact with the base region 62 and the source region 63. The drain electrode 52 is in contact with the drain region 60.

The gate electrode 53 is provided in a trench formed in the nitride semiconductor layer 10. The gate electrode 53 is a conductor. The gate electrode 53 is, for example, polycrystalline silicon containing n-type impurities or p-type impurities.

The gate insulating layer 54 is provided between the gate electrode 53 and the nitride semiconductor layer 10. The gate insulating layer 54 is provided between the gate electrode 53 and the drift region 61, between the gate electrode 53 and the base region 62, between the gate electrode 53 and the source region 63, and between the p-type gate electrode 53 and the electric field relaxation region 64.

The nitride semiconductor layer 10 is provided between the source electrode 51 and the drain electrode 52. The nitride semiconductor layer 10 is in contact with the source electrode 51 and the drain electrode 52. The nitride semiconductor layer 10 is, for example, a gallium nitride.

The n⁺-type drain region 60 is in contact with the drain electrode 52.

The drain region 60 contains n-type impurities. The n-type impurity is, for example, silicon (Si). The n-type impurity concentration of the drain region 60 is higher than the n-type impurity concentration of the drift region 61. The n-type impurity concentration of the drain region 60 is, for example, equal to or more than 1×10¹⁸ cm⁻³ and equal to or less than 1×10²¹ cm⁻³.

The n⁻-type drift region 61 is provided between the drain region 60 and the source electrode 51. The drift region 61 is in contact with the drain region 60.

The drift region 61 contains n-type impurities. The n-type impurity is, for example, silicon (Si). The n-type impurity concentration of the drift region 61 is, for example, equal to or more than 1×10¹⁵ cm⁻³ and equal to or less than 1×10¹⁷ cm⁻³.

The drift region 61 contains or does not contain carbon (C).

The p-type base region 62 is provided between the drift region 61 and the source electrode 51. The base region 62 is in contact with the drift region 61. The junction between the base region 62 and the drift region 61 is a pn junction. The base region 62 is in contact with the source electrode 51.

The base region 62 contains magnesium (Mg), which is a p-type impurity. The magnesium concentration of the base region 62 is, for example, equal to or more than 1×10¹⁸ cm⁻³ and equal to or less than 1×10²¹ cm⁻³.

The base region 62 contains or does not contain carbon (C).

When the vertical transistor 200 is turned on, a channel through which an on-current flows is formed in a portion of the base region 62 facing the gate electrode 53.

The n⁺-type source region 63 is provided between the base region 62 and the source electrode 51. The source region 63 is in contact with the source electrode 51.

The source region 63 contains n-type impurities. The n-type impurity is, for example, silicon (Si). The n-type impurity concentration of the source region 63 is higher than the n-type impurity concentration of the drift region 61. The n-type impurity concentration of the source region 63 is, for example, equal to or more than 1×10¹⁸ cm⁻³ and equal to or less than 1×10²¹ cm⁻³.

The p-type electric field relaxation region 64 is provided between the drift region 61 and the bottom of the trench. The drift region 61 is in contact with the gate insulating layer 54 at the bottom of the trench. The junction between the electric field relaxation region 64 and the drift region 61 is a pn junction. The electric field relaxation region 64 is electrically connected to the source electrode 51.

The electric field relaxation region 64 contains magnesium (Mg), which is a p-type impurity. The magnesium concentration of the electric field relaxation region 64 is, for example, equal to or more than 1×10¹⁸ cm⁻³ and equal to or less than 1×10²¹ cm⁻³.

The electric field relaxation region 64 has a function of reducing the electric field strength applied to the gate insulating layer 54 at the bottom of the trench, thereby improving the reliability of the gate insulating layer 54.

The first line defect 30a is provided spanning the drift region 61 and the base region 62. The first line defect 30a is provided, for example, spanning the drain region 60 and the drift region 61. The first line defect 30a is provided, for example, continuously between the drain electrode 52 and the source electrode 51. The first line defect 30a is in contact with, for example, the drain electrode 52 and the source electrode 51.

The first line defect 30a is, for example, a threading dislocation. The first line defect 30a is, for example, a threading screw dislocation.

The first linear carbon region 32a includes at least a part of the first line defect 30a. The first linear carbon region 32a is provided along the first line defect 30a.

The first linear carbon region 32a is in contact with, for example, the drift region 61. The first linear carbon region 32a is in contact with, for example, the base region 62.

The first linear carbon region 32a contains carbon (C). The carbon concentration of the first linear carbon region 32a is, for example, higher than the carbon concentration of the drift region 61. In addition, the carbon concentration of the first linear carbon region 32a is, for example, higher than the carbon concentration of the base region 62.

The second line defect 30b is provided spanning the drift region 61 and the electric field relaxation region 64. The second line defect 30b is provided, for example, spanning the drain region 60 and the drift region 61. The second line defect 30b is provided, for example, continuously between the drain electrode 52 and the bottom of the trench. The second line defect 30b is in contact with, for example, the drain electrode 52.

The second line defect 30b is, for example, a threading dislocation. The second line defect 30b is, for example, a threading screw dislocation.

The second linear carbon region 32b includes at least a part of the second line defect 30b. The second linear carbon region 32b is provided along the second line defect 30b.

The second linear carbon region 32b is in contact with, for example, the drift region 61. The second linear carbon region 32b is in contact with, for example, the electric field relaxation region 64.

The second linear carbon region 32b contains carbon (C). The carbon concentration of the second linear carbon region 32b is, for example, higher than the carbon concentration of the drift region 61. In addition, the carbon concentration of the second linear carbon region 32b is, for example, higher than the carbon concentration of the electric field relaxation region 64.

According to the second embodiment, since the first linear carbon region 32a is provided, the pn junction leakage current between the base region 62 and the drift region 61 is reduced. In addition, according to the second embodiment, since the second linear carbon region 32b is provided, the pn junction leakage current between the electric field relaxation region 64 and the drift region 61 is reduced. Therefore, it is possible to realize the vertical transistor 200 with reduced leakage current at the pn junction.

As described above, according to the second embodiment, it is possible to realize a semiconductor device with reduced leakage current at the pn junction.

In the first and second embodiments, the pn junction diode or the trench gate type MOSFET has been described as an example of the semiconductor device. However, embodiments can also be applied to other semiconductor devices. For example, embodiments can also be applied to a junction barrier Schottky (JBS) diode, a merged pin Schottky (MPS) diode, a planar gate type MOSFET, or a high electron mobility transistor (HEMT).

In addition, in the first and second embodiments, the case where the nitride semiconductor layer 10 is a gallium nitride (GaN) has been described as an example. However, embodiments can also be applied to cases where the nitride semiconductor layer 10 is a “GaN-based semiconductor” such as AlGaN, AlN, or InGaN.

While certain embodiments have been described, these embodiments have been presented by way of example only, and are not intended to limit the scope of the inventions. Indeed, the semiconductor device and the semiconductor device manufacturing method described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a second electrode;
a first nitride semiconductor region of n-type provided between the first electrode and the second electrode;
a second nitride semiconductor region of p-type provided between the first nitride semiconductor region and the first electrode, in contact with the first nitride semiconductor region, and containing magnesium (Mg);
a line defect provided spanning the first nitride semiconductor region and the second nitride semiconductor region; and
a linear region including at least a part of the line defect, provided along the line defect, and containing carbon (C).

2. The semiconductor device according to claim 1,
wherein the linear region is in contact with the first nitride semiconductor region and the second nitride semiconductor region.

3. The semiconductor device according to claim 1,
wherein the first nitride semiconductor region contains or does not contain carbon (C), and
a concentration of carbon (C) in the linear region is higher than a concentration of carbon (C) in the first nitride semiconductor region.

4. The semiconductor device according to claim 1,
wherein the second nitride semiconductor region contains or does not contain carbon (C), and
a concentration of carbon (C) in the linear region is higher than a concentration of carbon (C) in the second nitride semiconductor region.

5. The semiconductor device according to claim 1, further comprising:
a third nitride semiconductor region of n-type provided between the second electrode and the first nitride semiconductor region and having an n-type impurity concentration higher than an n-type impurity concentration of the first nitride semiconductor region.

6. The semiconductor device according to claim 1,
wherein a concentration of magnesium in the second nitride semiconductor region is equal to or more than 1×10¹⁸ cm⁻³.

7. The semiconductor device according to claim 1,
wherein the line defect is a threading screw dislocation.

8. The semiconductor device according to claim 1,
wherein the first electrode is in contact with the second nitride semiconductor region.

9. A semiconductor device manufacturing method, comprising:
performing a first ion implantation to implant carbon (C) into an n-type nitride semiconductor layer;
performing a second ion implantation to implant hydrogen (H) into the nitride semiconductor layer;
forming a first covering layer on a surface of the nitride semiconductor layer after the first ion implantation and the second ion implantation;
performing a first heat treatment after the forming the first covering layer;
removing the first covering layer;
performing a third ion implantation to implant magnesium (Mg) into the nitride semiconductor layer after the removing the first covering layer;
performing a fourth ion implantation to implant nitrogen (N) into the nitride semiconductor layer;
performing a fifth ion implantation to implant hydrogen (H) into the nitride semiconductor layer;
forming a second covering layer on a surface of the nitride semiconductor layer after the performing third ion implantation, the performing the fourth ion implantation, and the performing the fifth ion implantation;
performing a second heat treatment after the forming the second covering layer;
removing the second covering layer after the performing the second heat treatment; and
performing a third heat treatment after the removing the second covering layer.

10. The semiconductor device manufacturing method according to claim 9,
wherein the first heat treatment is performed in an atmosphere containing hydrogen.

11. The semiconductor device manufacturing method according to claim 9,
wherein the second heat treatment is performed in an atmosphere containing hydrogen.

12. The semiconductor device manufacturing method according to claim 9,
wherein a dose of hydrogen in the second ion implantation is larger than a dose of carbon (C) in the first ion implantation.

13. The semiconductor device manufacturing method according to claim 9,
wherein a dose of nitrogen in the fourth ion implantation is larger than a dose of magnesium (Mg) in the third ion implantation.

14. The semiconductor device manufacturing method according to claim 9,
wherein a dose of hydrogen in the fifth ion implantation is larger than a dose of magnesium (Mg) in the third ion implantation.

15. The semiconductor device manufacturing method according to claim 9,
wherein the third heat treatment is performed in an atmosphere containing argon, nitrogen, or helium.

16. The semiconductor device manufacturing method according to claim 9,
wherein the first covering layer is a silicon oxide, a silicon nitride, a silicon oxynitride, or an aluminum nitride.

17. The semiconductor device manufacturing method according to claim 9,
wherein the second covering layer is a silicon oxide, a silicon nitride, a silicon oxynitride, or an aluminum nitride.

18. The semiconductor device manufacturing method according to claim 9,
wherein the nitride semiconductor layer includes a threading screw dislocation.
